(19) United States
(12) Patent Application Publication
(10) Pub. No.: US 2002/0160100 A1
(43) Pub. Date: Oct. 31, 2002

(54) METHOD FOR REGULATING A COATING PROCESS UTILIZING THE INTENSITY OF A LIGHT BUNDLE

(76) Inventors: UWE SARBACHER, KARLSDORF (DE); WILBERT WINDELN, HEINSBERG (DE)

Correspondence Address: ROBERT W. BECKER & ASSOCIATES, 707 HIGHWAY 66 EAST, SUITE B, TIJERAS, NM, 87059, US

(21) Appl. No.: 09/508,646

(22) PCT Filed: Sep. 4, 1998
(86) PCT No.: PCT/EP98/05612

(30) Foreign Application Priority Data
Sep. 10, 1997 (DE) P 197 39 794.8

(51) Int. Cl. B05D 1/02; B05D 5/06

(52) U.S. Cl. 427/8; 427/424; 427/425; 427/162

(57) ABSTRACT

A method for regulating a coating process for the application of a layer onto a substrate having a diffracted structure is provided. The intensity of a light bundle falling onto a coated substrate and diffracted thereby is determined after transmission and/or reflection of the light bundle for at least the first order or a higher order, and this intensity is utilized as the actual value for regulating the layer thickness.

The invention relates to a method for regulating a coating process for applying a layer to a substrate.

During the application of layers to a substrate, it is necessary with numerous manufacturing and treatment processes that a specific layer thickness must be provided or maintained. During the manufacture of, for example, compact discs (CD's), a coating agent, for example a lacquer layer, or in the case of the manufacture of recordable CDs, so called CD-Rs, a pigment is applied to a so-called plastic disc with a dispenser and the lacquer or pigment is uniformly distributed over the disc by rotating the disc and by utilizing cylindrical forces. During the coating process, the thickness of the coating thus depends upon many factors, for example the type and consistency of the coating agent, the existing temperature, the speed or the duration, during which the substrate rotates. It is therefore very difficult, over reasonably long periods of time, to maintain constant parameters during the coating process that enable a coating of the substrates with a constant layer thickness. To monitor the coating thickness or the thickness layers provided thereby, it is therefore necessary with conventional manufacturing processes to interrupt the manufacturing process and to determine the respective layer thickness of the applied layer via spot checks, and as a function thereof to alter the parameters for the manufacturing process that influence the layer thickness, for example by appropriately altering the speed of the substrate or the duration of the substrate rotation. The productivity of conventional coating processes is therefore limited, which is particularly disadvantageous especially during the manufacture of CDs or CD-Rs as inexpensive mass produced products.

Although it is possible to provide the automatic manufacturing equipment with expensive, very complicated measuring devices, such as nuclear powered microscopic measuring devices, in order to determine the layer of thickness during the coating process and as a function thereof to alter the parameters for the coating, such measuring processes and devices lengthen a checking preparation and require a long measuring time. In addition, they are not only expensive but rather in particular are also subject to breakdown and require a lot of maintenance, so that this possibility is not suitable in conjunction with the manufacture of, for example, CDs as mass produced items.

From the publication JP 06-223418 A, abstract in the data bank WPI (Derwent), an apparatus is known with which the intensity of a diffracted light beam of zero order is measured, which is produced when the light beam is reflected at the surface of a transparent substrate that is disposed on a turntable. As a result, the thickness of an applied layer of an optical recording medium is measured.

The publication SU 947, 640 B, abstract in the data bank WPI (Derwent) discloses a method for measuring thin layers according to which the layer, the thickness of which is to be measured, is selectively etched in order to measure a reflected defraction light beam and from that to conclude the thickness of the layer. To measure the layer it is therefore necessary to alter the layer itself. By etching a structure into the layer that is to be measured, a “destructive” process is therefore utilized.

The publications H. H. Schlemmer, M. Mächler, J. Phys., E.Sci. Instrum. Vorrichtung. 18, 914 (1985); M. Mächler, M. Schlemmer, Zeiss Inform. 30. Vorrichtung. 16 (1988); U.S. Pat. No. 4,645,349, U.S. Pat. No. 4,984,894, U.S. Pat. No. 4,666,305, WO 96-33387 A1 and EP 0 772 189 A2 disclose respective methods and apparatus for measuring layer thicknesses according to which, however, diffraction processes are not utilized and in addition regulating methods are not utilized in conjunction with coating processes.

It is therefore an object of the invention to provide a method for regulating a coating process for the application of a layer onto a substrate, with the method being very simple, requiring little maintenance, and being economical to use, and also enabling a reliable determination and/or regulation of the layer that is to be applied onto a substrate during the coating process.

This object is inventively realized by a method for regulating a coating process for the application of a layer onto a substrate having a diffracted structure, whereby the intensity or the intensity alteration of a light beam or light bundle that falls upon the coated substrate is determined after its reflection and/or transmission for at least one order of the diffracted light bundle and is used as the actual or regulating value for the layer thickness. Due to the straightforward measures and components for carrying out the inventive method, a reliable and continuous determination of the layer thickness is possible during the coating process with simple means and at low cost. The maintenance expense for an apparatus for carrying out the method is also conceivably low.

Since the substrate has structures, as is the case, for example, by means of the so-called pre-grooves with CD-Rs, it is possible to determine the intensity alteration of at least one diffracted light bundle, for example the first order or the second order or also a higher order of the diffracted light bundle, and to utilize this as the actual or regulating value for the regulation of the layer thickness. The intensity alteration in particular of diffracted light bundles will be described in detail subsequently with the aid of specific embodiments.

Pursuant to one advantageous embodiment of the invention, the intensity or intensity alteration of the non-diffracted light beam is determined.

Pursuant to a further very advantageous embodiment of the invention, the intensity or intensity alteration of the non-diffracted and/or diffracted light bundle is determined for at least one wavelength of the light bundle. Due to the limitation to one or less wavelengths of the light bundle, it is possible in certain applications to determine a defined intensity.

However, it is particularly advantageous to simultaneously measure the intensity and/or the intensity alteration for a number of wavelengths, as a result of which ambiguities due to interference effects can be avoided.

The intensity or the intensity alteration of the diffracted light bundle can be carried out in transmission and/or in reflection.

Pursuant to a further advantageous embodiment of the invention, for regulation of a coating process not only the absolute intensity or the absolute intensity alteration of the reflected and/or transmitted light beam, but also the determination of the relative intensity or intensity alteration are possible and advantageous. In this connection, the relationship of the intensities of the outgoing and of the incoming light bundles are determined and are utilized as the actual or regulating value.

The stated objective is also realized with an initially mentioned method alternatively or in conjunction with the previously described measures in that the spectral distribution and/or the alteration of the spectral distribution of a light beam that falls upon the coated substrate is determined after its reflection and/or transmission and is utilized as the actual value for the regulation of the layer thickness. Also in the case of the determination of the spectral distribution and/or of the alteration of the spectral distribution this is possible for non-diffracted light beams or also with diffracted light beams, whereby the spectral distribution or alteration thereof in the last case is possible and advantageous not only for one order, for example the zero or the first order, but also for multiple orders. Spectral photometers are preferably utilized as receivers in the case of determination of the spectral distribution or alteration thereof.

The light sources are advantageously lasers, light emitting diodes (LED's), spectral lamps, halogen lamps, or thermal radiators, depending upon the application and the conditions. It is also advantageous to filter incoherent light spectra given off from a light source.

Pursuant to one advantageous embodiment of the invention, observed values are provided for the target or intended values in conjunction with the regulation. In order to avoid time consuming and laborious tests and prior coating processes to determine these observed values, it is also advantageous to utilize calculated values as target or intended values for the regulation. Especially when the substrate and/or the coating material is changed, and therewith a new disposition of the layer profile is necessary, a determination of observed values for the intended value of the regulation can be very time consuming. The target values for the regulation are therefore advantageously computer determined for a prescribed layer profile in order to save time. In this connection, it is advantageous to utilize known calculation methods in conjunction with the optics of these layers, as is known, for example, from Born &Wolf, Principles of Optics, 6^{th} Edition, Pergamon Press, especially pages 51-70.

In conjunction with the coating of structured substrates, for example for the manufacturer of CD-Rs, where the plastic substrate is manufactured with an injection molding tool to form the pre-grooves geometry, it is furthermore advantageous to undertake an analytic correction of the wear of the injection molding tool, the geometry of which, for example the depth of the pre-grooves, is noticeable during the manufacture of a large number of plastic substrates.

The invention, as well as embodiments and advantages thereof, will be explained in detail subsequently with the aid of an example of the coating of a CD-R with the aid of the figures, which show:

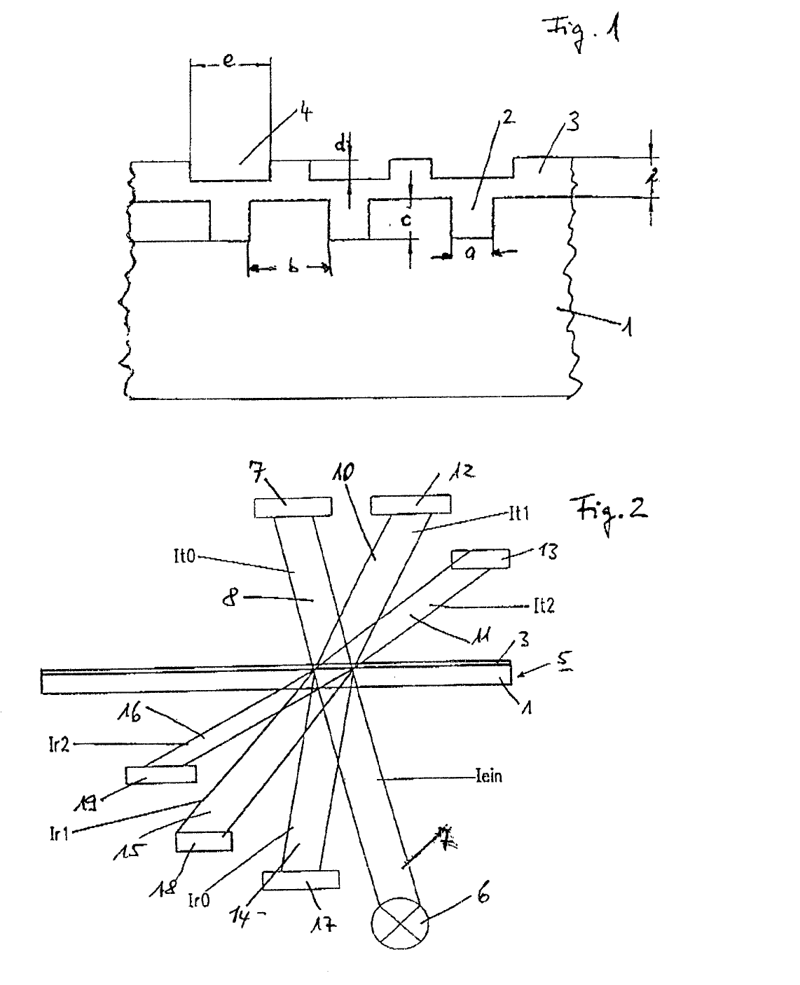

FIG. 1, a schematic cross-sectional view through one portion of a coated substrate for a CD-R, and

FIG. 2, a schematic illustration of the inventive method in conjunction with the coating of a substrate having a pre-groove geometry and being intended for CD-R manufacture.

As shown in FIG. 1, a substrate has formed on an upperside thereof a so-called pre-groove geometry, for example by injection molding of the substrate 1. In this embodiment, the upper surface of the substrate 1 has so-called pre-grooves 2 having a width “a” of about 450 nm at a constant spacing “b” of about 1600 nm, whereby the pre-grooves 2, at the constant spacing “b”, extend helically relative to one another. The pre-grooves 2 have a depth “c” that typically lies in a range between 50 and 200 nm. Disposed on the substrate 1 is an applied pigment or dye layer 3 that essentially extends over the entire surface of the substrate 1 and also fills the pre-grooves 2 of the substrate 1. Disposed above the pre-grooves 2 that are filled with the pigment are respective so-called grooves 4 in the form of sinks that result during settling of the pigment into the pre-grooves 2 of the substrate 1, and serve as a channel or track during the recording and reading of the CD-R. Although the illustration shows a right-angled shape for the groove 4 with the groove width, there normally exists an inclined or gradual transition from the crown to the base. The depth of the groove 3 is designated “d”, while the thickness of the pigment layer 3 in the regions beyond the pre-groove 2 and groove 4 is provided with the reference symbol “f”.

The structure and embodiment of a CD-R as well as the pre-grooved geometry thereof and the applied pigment layer is generally known and is described, for example, in the article Holstlag, et al., Jpn. J.Appl.Phys. Volume 31, Part 1, Nr. 2 B (1992) pages 484-493. To avoid repetition, reference is made to this publication and it is incorporated herein by this reference thereto.

FIG. 2 schematically illustrates the CD-R 5 with the substrate 1 and the pigment layer 3. A light source 6 emits an incoming light beam or bundle 7 in an intensity lein from below onto the CD-R 5, which goes therethrough and has a non-diffracted transmission light bundle 8 having an intensity It0, in other words as a transmission beam of the diffraction order zero, strikes a receiver 9, for example a spectral photometer, and its intensity is measured. However, the incoming light beam 7 that strikes the CD-R 5 from below is also diffracted at the pre-grooves 2, which due to their uniform spacing “e” form a diffraction screen. As a consequence, there results the transmission light bundle 10 of first order with the intensity It1 and the transmission light bundle 11 with the intensity It2, which fall upon respective further receivers 12 and 13 for measuring their intensity, which receivers can again be spectral photometers. However, the incoming light bundle 7 is also (partially) reflected in the CD-R 5 at the transition between the substrate 1 and the pigment layer 3, so that in conformity with the transmission light bundles 8, 10 and 11, reflection light bundles 14, 15, 16 result that fall upon appropriate receivers or detectors 17, 18, 19. The reflection light bundle 14 is not diffracted and has the intensity Ir0. The reflection bundle 10 is the diffraction light beam of first order with the intensity Ir1 and the reflection light bundle 16 is the diffraction beam of second order with the intensity Ir2. It is to be understood that the path of the beams could be reversed. In such a case, the incoming light beam or bundle 7 of the light source 6 falls upon the CD-R 5 from the side of the pigment layer 3. Many pigment layers transmit at specific wavelengths only so little light that the additional reflection, e.g. at the transition between the substrate 1 and the pigment layer 3, is very weak. A measurement is then practically not influenced at all by such reflection.

The complex computation index of the material of the pigment layer 3 is known as a function of the wavelength, i.e. can be measured by known methods. Furthermore, the geometry of the pre-grooves 2 and their orientation in the substrate 1, in other words the width “a” and the depth “c” of the pre-grooves 2 as well as their spacing “b” from one another is known. The pre-groove geometry is altered only slowly due to the wear of the injection molding tool. The alteration of the pre-groove geometry is therefore easy to regulate from time to time for determining the thickness of the pigment layer 3, if it is not otherwise negligible.

In contrast, the surface relief of the pigment layer 3 is not known, which is formed by the periodic structure of the grooves 4 with a groove depth “d” and the groove width “e” (see FIG. 1).

This surface relief of the pigment layer 3, i.e. the depth “d” and the width “e” of the grooves 4, can however be measured and established by the light bundle intensities It0, It1 and It2 of the transmitted light bundles 8, 10 and 11 and/or by the intensities Ir0, Ir1 and Ir2 of the reflected light bundles 14, 15 and 16.

Merely for the sake of completeness is mention made that the uniqueness of the measured parameters It0, It1 and It2, as well as Ir0, Ir1 and Ir2 is limited to phase differences that are less than half of the utilized light wavelengths. Since the depth “e” of the grooves 4, however, normally lies between 50 nm and 200 nm, this means anyway in practice and in particular with the transmission of the light bundle that there is no limitation if light having a wavelength greater than about 600 nm is used. In this connection, it is immaterial whether the diffracted light bundle is measured in transmission or in reflection. When measuring in transmission, the phase shift in the space interval 0 to 300 nm is considerably less than half of the light wavelengths of the visible spectral range. When measuring in reflection, there results for this spectral range greater ambiguity, especially when illuminating from the substrate side. These ambiguities can be eliminated only by a pre-knowledge of the more narrow depth of field in the process. The usable depth of field in this case can be expanded by simultaneously measuring at different wavelengths.

After the pre-groove geometry of the substrate 1, in other words the width “a” and the depth “b” of the pre-groove 2, is known and is constant, and the geometry of the pigment layer 3, in other words the depth “d” and the width “e” of the grooves 4, can be measured, only the constant thickness “f” of the pigment layer 3 is still unknown, which must be determined and regulated during the coating process. This thickness “f” affects the absorption of the transmitted, non-diffracted light bundle during an alteration during the application of the pigment layer 3, and hence affects the relationship of the intensity It0 of the transmitted light bundle of zero order and the intensity lein of the striking light bundle 7. By measuring this relationship there therefore results a measurement for the thickness “f” of the pigment layer 3 and a control actual value for regulation of parameters of the coating process, for example a regulation of the temperature of the pigment that is to be applied, or the speed or duration of the substrate rotation.

If the danger of ambiguities of the measurement ratio It0/lein exists due to interference effects, it is additionally advantageous and expedient to simultaneously measure It0/lein for a number of wavelengths, for example by using a spectral photometer.

For the target or desired magnitudes during the regulation it is sufficient if observed or empirical values are prescribed. A numeric determination of the values “d”, “e”, “f” is not necessary for a regulation. The determination of such empirical or observed values can, however, require a lot of time. In particular, when the type of pigment is changed a new provision of the layer profile is necessary. In order to save time, it is then advantageous to numerically determine the target values for a prescribed layer profile. For this purpose, the transmission through the substrate 1 and the pigment layer 3 is locally calculated for one period of the periodic structure utilizing conventional calculation processes for thin layers. Subsequently, there is effected for the calculated, complex amplitudes a resolution in flat waves, i.e. a Fourier transformation is carried out. Squaring the amplitude of the flat waves delivers the intensity of the individual diffraction orders. This simplified method of proceeding is physically not exact, since the coupling of the waves of different orders cannot be taken into account. Nonetheless, in practice there results sufficient precision, since the depths of the structures, in other words the values “c” and “d”, are at most 200 nm, in other words much less than their periodicity, i.e. of the pre-grooves 2 or grooves 4 of 1600 nm relative to one another.

The invention has previously been described with the aid of one exemplary embodiment in conjunction with CD-R's. However, to one having ordinary skill in the art modifications and embodiments are possible without thereby deviating from the inventive concept. For example, it is possible to determine the spectral distribution of the transmission of zero order and from that to determine the depth “d” and the width “e” of the grooves 4, so that the measurement of the insensitivities of diffraction light bundles of greater order is not necessary. Furthermore, it is also possible by appropriate use of the inventive method at various locations of a substrate to determine if the layer thickness is uniform over the entire surface.

1. Method for regulating a coating process for the application of a layer onto a substrate having a diffracted structure, whereby the intensity of a light bundle falling onto the coated substrate is determined after its transmission for at least one order of the diffracted light bundle and is utilized as the actual value of the regulation of the layer thickness.

2. Method according to claim 1, characterized in that the intensity of the non-diffracted light beam is determined.

3. Method according to one of the preceding claims characterized in that the intensity is determined for at lease one wavelength of the non-diffracted and/or the diffracted light bundle.

4. Method according to one of the preceding claims, characterized in that the intensity is simultaneously determined for numerous wavelengths.

5. Method according to one of the preceding claims, characterized in that the intensity of the diffracted light bundle is determined in transmission.

6. Method according to one of the preceding claims, characterized in that the intensity of the diffracted light bundle is determined in reflection.

7. Method according to one of the preceding claims, characterized in that the relative intensity alteration of the reflected and/or transmitted light bundle is determined.

8. Method for regulating a coating process for the application of a layer upon a substrate, characterized in that the spectral distribution of a light beam falling upon the coated substrate is determined after its transmission and/or reflection.

9. Method according to claim 8, characterized in that the intensity and/or intensity alteration of the spectral distribution is determined.

10. Method according to one of the preceding claims, characterized in that a laser light bundle is utilized.

11. Method according to one of the preceding claims, characterized in that a light beam given off by an incoherent light source is utilized.

12. Method according to claim 11, characterized in that the incoherent light source is a light emitting diode, a spectral lamp, a halogen lamp or a thermal radiator.

13. Method according to one of the preceding claims, characterized in that the light is spectrally filtered.

14. Method according to one of the preceding claims, characterized in that observed values are utilized as target values for the regulation.

15. Method according to one of the claims 1 to 13, characterized in that calculated values are utilized as target values for the regulation.

16. Method according to claim 15, characterized in that the transmission through the substrate and the applied layer, similar to the calculation for thin layers, is locally calculated for one period of a periodic structure.

17. Method according to one of the preceding claims, characterized in that the substrate is a plastic disc.

18. Method according to one of the preceding claims, characterized in that the layer that is to be applied comprises a pigment.

19. Method according to one of the preceding claims, characterized for the manufacture of compact discs (CD's).

20. Method according to one of the claims 1 to 18, characterized for the manufacture of recordable, compact discs (CD-R's).
